(19) United States
(12) Patent Application Publication
(10) Pub. No.: US 2020/0073017 A1
(43) Pub. Date: Mar. 5, 2020

(54) Integrated Illumination Device and Lightning Detector

(71) Applicant: Marine Accessories Corporation, Knoxville, TN (US)

(72) Inventors: Anthony Duane Williams, Alcoa, TN (US); John Clarke, Knoxville, TN (US)

(73) Assignee: Marine Accessories Corporation, Knoxville, TN (US)

(21) Appl. No.: 16/560,569

(22) Filed: Sep. 4, 2019

Related U.S. Application Data
(60) Provisional application No. 62/727,238, filed on Sep. 5, 2018.

(51) Int. Cl. G01W 1/16; G01R 29/08; B63B 49/00; B63B 45/08; B63B 45/04

(52) U.S. Cl. CPC G01W 1/16; G01R 29/0842; B63B 49/00; B63B 2201/08; B63B 45/04; B63B 2201/02; B63B 45/08

(57) ABSTRACT

An integrated illumination device and lightning detector for boats that is operable as a conventional navigation light and including a lighting detector that generates an output signal in response to the presence of lightning. In response to the presence of lightning and the generation of the output signal by the lightning detector, a visual signal or an audible signal or both is generated to warn and notify occupants of the boat of the presence of lightning.

### CROSS-REFERENCE TO RELATED APPLICATION

This application claims priority to U.S. Provisional Application No. 62/727,238 filed Sep. 5, 2018, entitled INTEGRATED ILLUMINATION DEVICE AND LIGHTNING DETECTOR, incorporated herein by reference in its entirety.

### FIELD

This disclosure relates to the field of illumination devices and lightning detection devices. More particularly, this disclosure relates to an integrated illumination device and lightning detector that is particularly suitable with marine vehicles such as boats.

### BACKGROUND

When boating, illumination is needed in certain circumstances, such as at night to warn others of the presence of the boat. In addition, when boating, it is important to be vigilant for approaching weather conditions such as lightning. A need exists for a device that is suitable for both purposes and which is configured to be easily located on a boat.

### SUMMARY

The above and other needs are met by an integrated illumination device and lightning detector for boats, and a boat equipped with the same.

In one aspect, an integrated illumination device and lightning detector according to the disclosure includes a base configured for mounting to a surface; a lightning detector located on the base and operable to generate a signal in response to detection of lightning for warning of the presence of lightning; an elongate rod extending upwardly from the base and having a terminal end; an illumination source located at the terminal end of the elongate rod and selectively operable to generate visible illumination; and electrical wires connectable to a power source and extending through the base and the elongate rod and in electrical communication with the lightning detector and the illumination source.

In another aspect, a boat according to the disclosure includes a boat having a cockpit with an audible device and the boat also having a location on the boat that is a vertically highest location on the boat; and an integrated illumination device and lightning detector mounted on the boat.

The integrated illumination device and lightning detector includes a base mounted to the vertically highest location on the boat, an elongate rod extending upwardly from the base and having a terminal end, an illumination source located at the terminal end of the elongate rod and selectively operable to generate visible illumination, a lightning detector located on the base and operable to generate a signal in response to detection of lightning for warning of the presence of lightning, and electrical wires connectable to a power source and extending through the base and the elongate rod and in electrical communication with the lightning detector, the illumination source and the audible device of the boat.

In response to the presence of lightning, the signal generated by the lightning detector is conducted by the electrical wires to the audible device located on the cockpit of the boat to provide an audible alarm and to the illumination source to provide a visual alarm.

### BRIEF DESCRIPTION OF THE DRAWINGS

Further advantages of the disclosure are apparent by reference to the detailed description when considered in conjunction with the figures, which are not to scale so as to more clearly show the details, wherein like reference numbers indicate like elements throughout the several views, and wherein:

FIG. 1 shows an integrated illumination device and lightning detector according to the disclosure installed on a boat.

FIG. 2 is a close-up view of an integrated illumination device and lightning detector according to the disclosure.

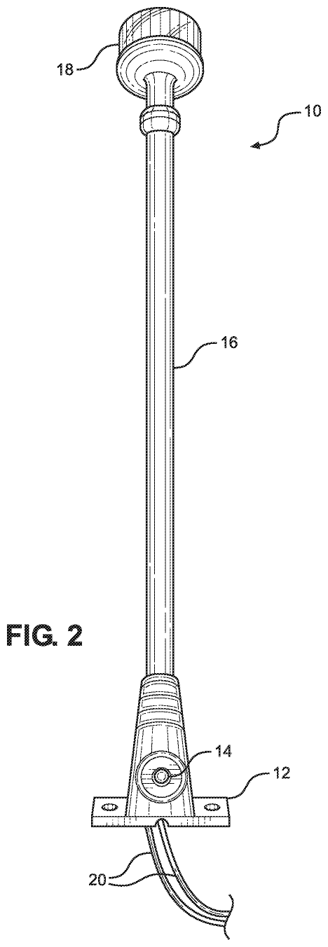

### DETAILED DESCRIPTION

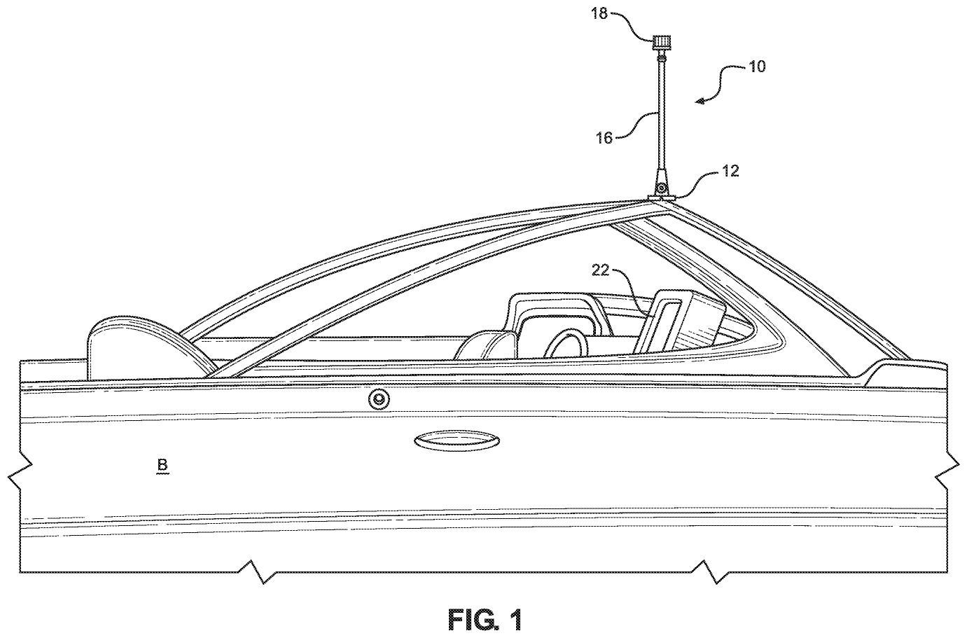

With initial reference to FIG. 1, there is shown a device 10 providing an integrated illumination device and lightning detector according to the disclosure. The device 10 is particularly configured for use with marine vehicles such as a boat B.

In such use, the device 10 is preferably mounted at an elevated position and in one embodiment can be attached as shown to be the highest point on the boat B. This advantageously provides a navigation light as the highest point of the boat B, per United States Coast Guard regulations, and also provides a lightning detector proximate the highest point of the boat B. The device 10 may also be attached adjacent the fore or aft of the boat B.

The device 10 includes a mount or base 12, a lightning detector 14, elongate rod 16, illumination source 18, and wires 20.

The base 12 is mountable to the boat B and preferably houses the lightning detector 14. The elongate rod 16 extends upwardly from the base 12 with the illumination source 18 being located at the terminal or highest end of the elongate rod 16. The base 12 may be configured to enable the rod 16 to be pivoted to a lowered position to facilitate transport and storage of the boat B having the device 10 mounted thereto.

The lightning detector 14 is preferably incorporated onto the base 12 and may include alarms such as an illumination alarm or an audible alarm integrated into the lightning detector. However, in a preferred embodiment, the illumination alarm is provided by activating the illumination source 18 and the audible alarm is provided by activating an audible device associated with the boat B.

The lightning detector 14 is operable to generate an output signal when within a relative proximity to lightning. A preferred lightning detector is available from Precision Measurement Technologies located in Clearwater, Fla. under the model/name AS3935 Franklin Lightning Sensor. This preferred lightning detector includes a programmable lightning sensor circuit that utilizes an RF receiver and an associated algorithm that is operable to detect the presence and approach of lightning up to a distance of 24 miles.

The illumination source 18 may be provided by various types of light bulbs, light emitting diodes, or other electrical illumination devices. The illumination source 18 is preferably provided by an array of light emitting diodes, preferably having at least two different color outputs, such as white and red, and preferably at least three different color outputs, such as white, red and green.

The wires 20 connect to the illumination source 18, a source of electrical power, such as a battery of the boat and control circuitry, such as an on-off switch to enable selective operation of the illumination source 18 as a conventional boat navigation light. The wires 20 also connect to the lightning detector 14. In addition, the wires 20 may connect to an audible device, such as a horn or buzzer, or a radio associated with the boat B and in electrical communication with the lightning detector to be operated as an audible signal or alarm in the event lightning is detected by the lightning detector 14. The horn, buzzer, or radio or other audible devices are preferably standard audible devices of the boat B commonly integrated into a cockpit 22 of the boat B.

In operation, the device 10 is functional as a conventional navigation light and can be selectively turned off and on as by an on/off switch. However, in the event the lightning detector 14 is activated by the presence of lightning, the device 10 functions to indicate such detection of lightning to generate an output signal and provide warning. The warning may be visual or audible or both.

For example, in response, the illumination device 18 may be in electrical communication with the lightning detector 14 and be activated to flash or strobe or change color or the like in the event lightning is detected by the lightning detector 14. In addition, an audible alarm or signal may be generated as by an associated buzzer or activating a radio or horn or buzzer of the boat to generate an audible alarm.

As static charge often results from the presence of lighting, the device 10 is advantageously configured to withstand and dissipate such static charge and to remain operational.

Accordingly, it will be appreciated that the disclosure provides an integrated illumination device and lightning detector that is particularly suitable for use with boats and that is operable as a conventional navigation illumination device and including a lightning detector that generates an output signal in response to the presence of lightning. In response to the presence of lightning and the generation of the output signal by the lightning detector, a visual signal or an audible signal or both is generated to warn and notify occupants of the boat of the presence of lightning.

The foregoing description of preferred embodiments for this disclosure has been presented for purposes of illustration and description. It is not intended to be exhaustive or to limit the disclosure to the precise form disclosed. Obvious modifications or variations are possible in light of the above teachings. The embodiments are chosen and described in an effort to provide the best illustrations of the principles of the disclosure and its practical application, and to thereby enable one of ordinary skill in the art to utilize the disclosure in various embodiments and with various modifications as are suited to the particular use contemplated. All such modifications and variations are within the scope of the disclosure as determined by the appended claims when interpreted in accordance with the breadth to which they are fairly, legally, and equitably entitled.

1. An integrated illumination device and lightning detector, comprising:
a base configured for mounting to a surface;
a lightning detector operable to generate a signal in response to detection of lightning for warning of the presence of lightning;
an elongate rod extending upwardly from the base and having a terminal end;
an illumination source located at the terminal end of the elongate rod and selectively operable to generate visible illumination; and
electrical wires connectable to a power source and extending through the base and the elongate rod and in electrical communication with the lightning detector and the illumination source.

2. The integrated illumination device and lightning detector of claim 1, wherein the lightning detector is operable to send a signal to the illumination source to activate the illumination source in response to detection of lightning by the lightning detector.

3. The integrated illumination device and lightning detector of claim 1, further comprising an audible device in electrical communication with the lightning detector to provide an audible alarm, wherein the audible device is activated in response to detection of lightning by the lightning detector.

4. The integrated illumination device and lightning detector of claim 3, wherein the audible device is mounted on a cockpit of the boat.

5. The integrated illumination device and lightning detector of claim 4, wherein the audible device comprises one or more of a horn, buzzer, or radio.

6. The integrated illumination device and lightning detector of claim 1, wherein the lightning detector is located on the base and the base is mounted on a boat and the terminal end of the elongate rod defines a highest point of the boat.

7. A boat, comprising:
a boat having a cockpit with an audible device and the boat also having a location on the boat that is a vertically highest location on the boat; and
an integrated illumination device and lightning detector mounted on the boat, comprising:
base mounted to the vertically highest location on the boat,
an elongate rod extending upwardly from the base and having a terminal end,
an illumination source located at the terminal end of the elongate rod and selectively operable to generate visible illumination,
a lightning detector located on the base and operable to generate a signal in response to detection of lightning for warning of the presence of lightning, and
electrical wires connectable to a power source and extending through the base and the elongate rod and in electrical communication with the lightning detector, the illumination source and the audible device of the boat,
wherein, in response to the presence of lightning, the signal generated by the lightning detector is conducted by the electrical wires to the audible device located on the cockpit of the boat to provide an audible alarm and to the illumination source to provide a visual alarm.
